(19) United States
(12) Patent Application Publication
(10) Pub. No.: US 2006/0099808 A1
(43) Pub. Date: May 11, 2006

(54) Electric viscous fluid device and electronic equipment

(75) Inventor: Shinichiro Kondo, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Sony Corporation, Tokyo (JP)

(21) Appl. No.: 10/522,623

(22) PCT Filed: Aug. 5, 2003
(86) PCT No.: PCT/JP03/09925

§ 371 Date: Dec. 13, 2005

(51) Int. Cl. G09B 21/00; H01L 21/44; F16F 9/53; F16F 9/14

(52) U.S. Cl. 438/674; 434/113; 188/267.1; 192/58.42; 267/64.15

(57) ABSTRACT

An electrorheological fluid device and an electronic apparatus, which realize various hardness or tension in a portion of the device or apparatus to which a human body touches, enabling application to a product that needs to have portability. An electrorheological fluid device is formed by including: a container capable of containing fluid internally; a pair of electrodes having flexibility, disposed in the container so as to oppose each other; and an electrorheological fluid having an elastic property changeable in accordance with an electric field generated between the electrodes, the electrorheological fluid being contained in the container and disposed between the electrodes. By using the electrorheological fluid device to various electronic apparatus, the hardness, tension, texture, shape, or the like of the apparatus can be electrically controlled.

### TECHNICAL FIELD

The present invention relates to an electrorheological fluid device including an electrorheological fluid having changeable elastic properties contained in a container, and an electronic apparatus using the same.

### BACKGROUND ART

Many products having predetermined shapes and parts constituting them use wood, metals, resins, and the like as raw materials, and they are generally constructed so that they keep the shapes which are once determined in the stage of production. An elastic site can be changed in shape by an external force, exclusive of a site comprised of a plastic material, and, when the external force, which is within the elastic limit, is removed, the site returns to the original shape.

The inherently hard products or parts can be changed in shape and other physical properties not only by the mechanical force mentioned above but also by another method. For example, when an electric current of a certain value or higher flows through a fuse, the constituent component of the fuse is melted or deformed to shut the electric current out. In a solenoid valve, electrical control of a magnetic force can switch the component as a valve. Further, a shape memory alloy is deformed depending on the temperature, and can return to the original shape.

On the other hand, if the product or part, which is formed from a soft material, or a hard material but comprised of further smaller units, or which has a very small thickness, it can be changed in shape. In a vinyl product packed with a gel, both the outer material and the inner material are soft, and therefore the shape of the product can be freely changed within a certain limit. In addition, a doll, such as a robot comprised of smaller parts joined together by components, e.g., joints, a folding mobile phone, and the like can be changed in shape, although the degree of freedom is low. Further, as typical examples of the materials which are increased in flexibility by lowering the dimension of the shape so that they can be changed in shape, there can be mentioned plastics. Specifically, a plastic, which constitutes a large, thick, and solid object, such as a housing for electrical appliance, is difficult to be bent, but, when the plastic is as thin as a deskpad, it exhibits elasticity. Further, when the plastic is processed into a tube, in other words, one-dimensional shape, the degree of freedom in the change of shape is increased.

Paper itself has certain tension, but it loses strength depending on the way of holding it and cannot keep its shape. Fabric itself has tension lower than that of paper and cannot keep its shape similarly. The paper and fabric have an advantage in that they are lightweight and can be folded into a small piece or rounded and have excellent portability, but they have a problem in that they are difficult to keep their spread shapes during the use.

As mentioned above, a material of wood, a metal, or a certain resin is a relatively hard material, and it is desired that, for example, a portion which a human body touches is soft from the viewpoint of preventing the human body from being injured, but the products or parts are generally constructed so that they keep their shapes, and used as they are hard after the production, so that the hardness may cause a human body to be injured. Further, the use of a hard material restricts the shape or size of the product, so that the range of the degree of desired tension or texture is almost fixed to that determined at the production.

With respect to the portability of a product, the use of a material, such as paper or fabric, improves the portability since it can be folded into a small piece or rounded, although it has only a poor ability to maintain the shape. However, when a product is formed from an inherently soft material, for making the product to keep the shape by itself, the product having a space therein is packed with filler, or a hard frame or the like is incorporated into the edge of the product. In this case, the product can no longer be folded, thus lowering the portability.

In this situation, a task of the present invention is to provide an electrorheological fluid device and an electronic apparatus, which realize satisfactorily changeable hardness or tension in a portion of the device or apparatus which a human body touches, enabling application to a product that needs to have portability.

### DISCLOSURE OF THE INVENTION

For solving the above technical problems, the electrorheological fluid device of the present invention is characterized in that it includes: a container capable of containing fluid therein; a pair of electrodes having flexibility, disposed in the container so that the electrodes are opposite to each other; and an electrorheological fluid contained in the container and disposed between the electrodes, and having an elastic property changeable in accordance with an electric field generated between the electrodes.

The electrorheological fluid is disposed in a container, together with a pair of electrodes, and hence changes in its elastic property in accordance with an electric field generated between the electrodes. Therefore, when the container is fitted to an apparatus body or housing having such portability that it can be rolled or folded, the shape of the apparatus body or housing to which the container is fitted can be controlled to be changed in accordance with the change of the elastic property of the electrorheological fluid contained in the container, and further the shape of the apparatus body or housing can also be kept spread or unfolded. In addition, a portion which a human body touches can be elastic or hard depending on the shape of the container, and, for example, can offer comfortable feeling of touch to a human body.

The electronic apparatus of the present invention is characterized in that it includes: an apparatus body having flexibility; a container, fitted to the apparatus body, being capable of containing fluid therein; a pair of electrodes having flexibility, disposed in the container so that the electrodes are opposite to each other; and an electrorheological fluid contained in the container and disposed between the electrodes and having an elastic property changeable in accordance with an electric field generated between the electrodes.

Like in the electrorheological fluid device mentioned above, in the electronic apparatus of the present invention, the electrorheological fluid is disposed in a container, together with a pair of electrodes, and changes in its elastic property in accordance with an electric field generated between the electrodes. The container is fitted to an apparatus body having flexibility, and therefore the electrorheological fluid contained in the container changes its elastic property in accordance with the electric field to permit the apparatus body rolled or folded to return to the original shape.

Further, another electronic apparatus of the present invention is characterized in that it includes: an apparatus body; a container, fitted to the apparatus body, being capable of containing a fluid therein; a pair of electrodes disposed in the container so that the electrodes are opposite to each other; and an electrorheological fluid contained in the container and disposed between the electrodes, having an elastic property changeable in accordance with an electric field generated between the electrodes.

The apparatus body is not limited to one having flexibility, but may be of a structure having a channel formed in part of the body or of a structure having a switching portion, and the electrorheological fluid contained in the container changes in an elastic property to enable switching control of the channel or switching section.

### BRIEF DESCRIPTION OF THE DRAWINGS

FIG. 1 is a diagrammatic perspective view showing an electronic apparatus according to one embodiment of the present invention, wherein (a) shows the electronic apparatus in which the electrorheological fluid device is controlled to be in the off state, and (b) shows the electronic apparatus in which the electrorheological fluid device is controlled to be in the on state.

FIGS. 2A and 2B are views showing the basic structure of an electrorheological fluid device mounted on the electronic apparatus of the present invention, wherein FIG. 2A is an exploded perspective view of the stacked structure, and FIG. 2B shows the states of the electrorheological fluid according to the change of the voltage between the electrodes.

FIGS. 3A and 3B are views showing one example of the electrorheological fluid device in which electrorheological fluid elements are arranged in a matrix form, wherein FIG. 3A is an exploded perspective view of the stacked structure, and FIG. 3B shows the states of the electrorheological fluid according to the change of the voltage between the electrodes.

FIGS. 4A and 4B are views for explaining the driving mode, wherein FIG. 4A is a diagrammatic view showing one example of a passive matrix mode, and FIG. 4B is a diagrammatic view showing one example of an active matrix mode.

FIGS. 5A and 5B are perspective views showing examples of the construction of the electrorheological fluid device of the present invention, wherein FIG. 5A is an exploded perspective view showing an example in which a container for covering the side portion of an electrorheological fluid is formed, and FIG. 5B is exploded perspective views showing an example in which a container for completely covering the whole of the electrorheological fluid and electrodes is formed.

FIGS. 6A and 6B are views showing one example of the electronic apparatus of the present invention, wherein FIG. 6A is a perspective view showing the electronic apparatus which has been folded, and FIG. 6B is a perspective view showing the electronic apparatus which has been unfolded.

FIG. 7 is an exploded perspective view showing the structure of a substantially flat-plate form electrorheological fluid device of the present invention.

FIG. 8 is a perspective view of one example of the electronic apparatus of the present invention, in which an electrorheological fluid device is formed on the entire top surface of a substrate.

FIG. 9 is a perspective view of one example of the electronic apparatus of the present invention, in which an electrorheological fluid device having a shape of substantially square is formed on the top surface of a substrate.

FIG. 10 is a perspective view of one example of the electronic apparatus of the present invention, in which a substantially square-shaped electrorheological fluid device which further extends along the diagonals is formed on the top surface of a substrate.

FIG. 11 is a perspective view of one example of the electronic apparatus of the present invention, in which an electrorheological fluid device having a shape of substantially square which further extends along the crisscross is formed on the top surface of a substrate.

FIG. 12 is a perspective view of one example of the electronic apparatus of the present invention, in which a plurality of strip-shaped electrorheological fluid devices parallel to one another are formed on the top surface of a substrate.

FIG. 13 is a perspective view of one example of the electronic apparatus of the present invention, in which an electrorheological fluid device having a checkered pattern is formed on the top surface of a substrate.

FIG. 14 is a perspective view of one example of the electronic apparatus of the present invention, in which an electrorheological fluid device is formed so as to go around the sidewall of a substrate.

FIG. 15 is a perspective view of one example of the electronic apparatus of the present invention, in which an electrorheological fluid device is formed on the entire top surface and entire sidewall of a substrate.

FIG. 16 is a perspective view of one example of the electronic apparatus of the present invention, in which laminates, each having an electrorheological fluid device formed on the entire surface of a substrate, are stacked on one another.

FIG. 17 is a perspective view showing the structure of a substantially cylindrical electrorheological fluid device of the present invention.

FIG. 18 is a perspective view of one example of the electronic apparatus of the present invention, in which a substantially square-shaped electrorheological fluid device is formed on the top surface of a substrate.

FIG. 19 is a perspective view of one example of the electronic apparatus of the present invention, in which electrorheological fluid devices are formed at the corner portions on the sidewall of a substrate.

FIG. 20 is a perspective view of one example of the electronic apparatus of the present invention, in which a substantially square-shaped electrorheological fluid device which further extends along the diagonals is formed on the top surface of a substrate.

FIGS. 21A to 21D are perspective views showing examples of housings for the electronic apparatus in which the electrorheological fluid devices are arranged, wherein FIG. 21A is a view showing an example of the arrangement of the electrorheological fluid devices in a housing which can be curved, FIG. 21B is a view showing the housing in a curved state, FIG. 21C is a view showing an example of the arrangement of the electrorheological fluid devices in a housing which can be partially deformed, and FIG. 21D is a view showing the housing in a bent state.

FIG. 22 is a diagrammatic perspective view showing a flexible display device as one example of the electronic apparatus of the present invention.

FIG. 23 is a perspective view showing an example of earphone-type network audio equipment as one example of the electronic apparatus of the present invention.

### BEST MODE FOR CARRYING OUT THE INVENTION

The electrorheological fluid device and the electronic apparatus of the present invention individually have a structure such that the elastic properties of the electrorheological fluid contained in the container are changed to make the device or apparatus to change in hardness, tension, texture, or shape, or to be mechanically moved.

First, the electrorheological fluid (called ER fluid for short) used in the present invention is a fluid such that application of an electric field to electrodes causes the substance disposed between the electrodes to remarkably change in viscosity. More specifically, a fluid which contains fine particles (dispersed phase) having polarization properties and having a diameter of about 0.1 to 100 μm dispersed in electrical insulating liquid (dispersion medium), wherein when an external electric field is applied to the suspended fluid, a phenomenon occurs in which the apparent viscosity of the fluid remarkably increases. As the fine particles, various materials, such as aluminosilicate, polymers, e.g., polyaniline and polypyrrole, and fullerene, can be used. On the other hand, as the dispersion medium, a wide selection of solvents, such as silicone oil, kerosine, mineral oil, and poly chlorinated biphenyl, can be appropriated. When an electric field is applied to the colloid, the solid particles are connected to one another due to the polarizability effect to form a very small cilium-like form in the direction between the electrodes, so that the viscosity or elastic coefficient of the whole of the electrorheological fluid drastically changes, thus changing the fluid from the liquid (colloidal) state to the solid (gel) state. This change of the viscosity occurs in a period of time as short as several milliseconds and is reversible. Only a slight electric current flows between the electrodes, and hence the power consumption is very small (see, for example, “Electrorheological Fluids” by Tian Hao, Advanced Materials, Vol. 13, No. 24, pp. 1,847-1,857, 2001).

The effect in which the viscosity remarkably changes due to an electric field is found for the first time in the studies and discovery made by Willis Winslow in 1949 (reference literature: W. M. Winslow, Journal of Applied Physics, Vol. 20, pp. 1137-1140, 1949), and is called Winslow effect or electrorheological effect (ER effect) . Commercial applications utilizing the change of the viscosity of an electrorheological fluid to a clutch, a damper, a valve, and the like, which electrically control the mechanical force derived from the viscosity, have already been proposed, and, as a patent of this technique, U.S. Pat. No. 3,101,081 is known, and, in addition, various applications including a tactile sensation apparatus for finger disclosed in U.S. Pat. No. 3,073,712 are considered.

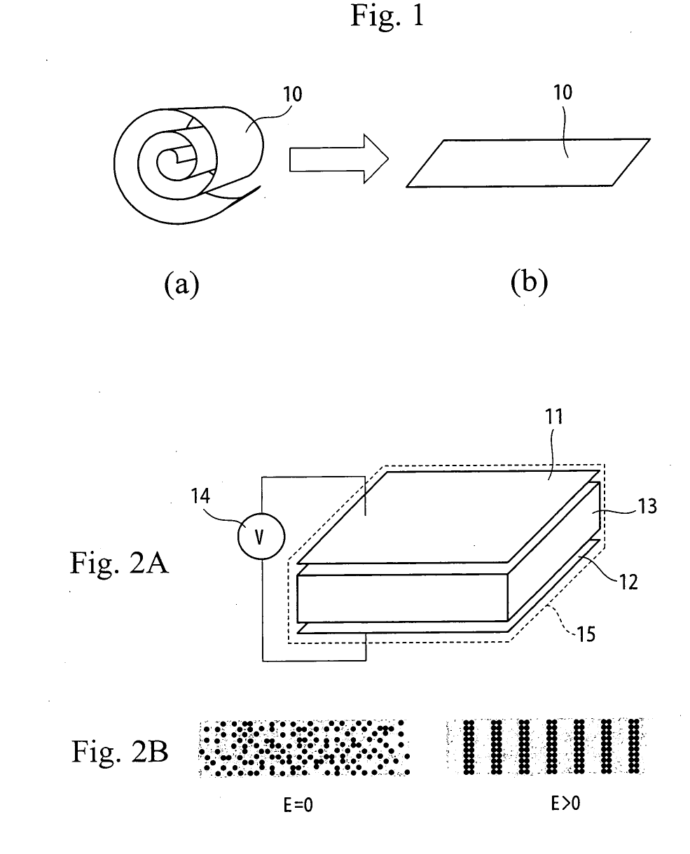

In view of the above-mentioned properties of an electrorheological fluid, a characteristic feature of the present invention resides in that the properties of the electrorheological fluid are applied to controlling of the shape of an electronic apparatus, and the present invention is an advantageous technique especially for an electronic apparatus having a flexible basic structure. FIG. 1 is a view showing an electronic apparatus according to one embodiment the present invention. An apparatus body 10 is of a film-form structure having flexibility, and the apparatus body 10 is provided with the below-described electrorheological fluid device. The electrorheological fluid device controlled to be in the off state is shown in (a) of FIG. 1, wherein the apparatus body 10 is wound. In contrast, when the electrorheological fluid device is controlled to be in the on state, as shown in (b) of FIG. 1, the apparatus body 10 is controlled to spread and be in a flat plate form.

The apparatus body 10 is a member for constituting products of various electronic apparatuses or parts thereof, and it can be products or parts of various apparatuses, such as film-form mobile phones, information processing units, e.g., PDAs (Personal digital Assistants) and computers, displays, audio reproduction apparatuses, remote controllers, sensors, batteries, loudspeakers, heaters, personal recognition apparatuses for electronic card or the like, analysis machines, measurement apparatuses, input/output apparatuses, e.g., tablets and touch panels, glasses, clocks, headphones, earphones, and electronic circuits.

The apparatus body 10 is comprised of a material having flexibility, and, as examples of the materials, there can be mentioned various materials, such as thin polymer organic materials, plates and films of glass, ceramic, wood, a metal, and the like, and fabric woven by paper or natural or artificial fiber, and nonwoven fabric. The apparatus body 10 is not necessarily comprised of a single body, and may be comprised of a plurality of pieces which are made of a relatively hard material, and which are movably connected to one another.

FIGS. 2A and 2B are views showing the basic construction of an electrorheological fluid device mounted on the electronic apparatus. As shown in FIGS. 2A and 2B, an electrorheological fluid 13 is disposed in a space between a pair of flat-plate form electrodes 11, 12, and a power source 14 is connected to the electrodes 11, 12 for forming an electric field between the electrodes. The flat-plate form electrodes 11, 12 are substantially square in the example shown in the figure, but they can be in an arbitrary form, and they are formed in a container 15 comprised of, for example, a polymer film material indicated by the dotted line in the figure. An example of producing the flat-plate form electrodes 11, 12 is, for example, a method in which a conductive thin film is formed inside the container 15 comprised of a polymer film material by a thin film formation process, such as a vacuum evaporation technique, a deposition technique, a plating technique, a sputtering technique, or a lamination technique. Alternatively, the electrodes maybe formed from a conductive material having flexibility, such as a conductive rubber sheet. That is, the electrodes 11, 12 are comprised of a thin film or flat-plate form member of a conductive material, and, especially in the use which changes in the shape, it is preferred that the electrode per se has flexibility. Here, the flexibility of the electrode includes the case where an electrode comprised of a plurality of relatively hard electrode pieces which are electrically connected to one another, and which can be curved or twisted totally. When the electrode is formed from a conductive material having flexibility, such as a conductive rubber sheet, for example, a rubber sheet having a thickness as small as about 100 μm may be used.

The electrorheological fluid 13 is a fluid such that, as mentioned above, application of an electric field to the electrodes causes the substance disposed between the electrodes to remarkably change in viscosity, more specifically, a fluid which contains fine particles having polarizable properties and having a diameter of about 0.1 to 100 μm dispersed in electrical insulating liquid (dispersion medium) wherein, when an electric field is applied to the suspended fluid from the electrodes 11, 12, the elastic coefficient of the fluid remarkably changes. Examples of materials used in the electrorheological fluid 13 include amorphous silicate ceramic, and, especially, it is known that aluminosilicate shows a strong electrorheological effect. Aluminosilicate contains a group of zeolite represented by a general formula: M_{(x/n)}[(AlO₂)ₓ(SiO₂)_{y}].wH₂O (where M represents a metal cation having average valence n or a mixture of metal cations, and each of x, y, and w is an integer), including clay, such as saponite and montmorillonite, 3A, 5A, and X-type zeolite, and various types of molecular sieves. Not only a luminosilicate but also a conductive organic material or polymer material can constitute the fine particles to be dispersed. Examples of polymer materials include oxidized polyacrylonitrile, polyaniline, poly(p-penylene), ionized dye materials, polypyrrole and derivatives thereof, and polythiophene, and these materials generally have electronic conduction properties due to the π-conjugated bond structure. In addition, carbonaceous materials and fullerene are also useful as a dispersible material, and examples of carbonaceous materials thermally treated include coal, liquid coal, coke, petroleum, resins, carbonblack, paraffin, olefin, pitch, tar, aromatic compounds (naphthalene, biphenyl, naphthalenesulfonic acid, anthracenesulfonic acid, and phenanthrenesulfonic acid), and polymers (polyethylene, polymethyl acrylate, polyvinyl chloride, phenolic resins, and polyacrylonitrile). Further, it is known that superconducting materials, such as YB₂Cu₃O₇₋ₓ, NdBa₂Cu₃Oₓ, YbBa₂Cu₃Oₓ, and Bi₂Sr₂CaCu₂O₈₊ₓ, show an electrorheological effect in, for example, silicone oil at room temperature, and these superconducting materials may be used.

The electrorheological fluid device generally having the above-described structure is operated by largely changing the viscosity of the electrorheological fluid according to the voltage applied from the power source 14. That is, when the power source 14 is in the off state and the voltage E applied to the electrodes 11, 12 is zero (E=0), the fine particles responsible for electrorheological properties are dispersed in the dispersion medium. On the other hand, when the power source 14 is in the on state and the voltage E applied to the electrodes 11, 12 is a certain value larger than zero (E>0), the fine particles responsible for electrorheological properties are connected to one another due to the polarizability effect to form a very small cilium-like form in the direction along the electric field between the electrodes. According to the state of aggregation of the fine particles, the viscosity or elastic coefficient of the fluid drastically changes, so that the fluid is changed from the liquid state (colloidal state) to the solid state (gel state) in a period of time as very short as several milliseconds. The phase changing between the liquid state and the solid state can change the hardness or texture outside of the container 15, or the shape of a portion continuing the container 15, e.g., the apparatus body.

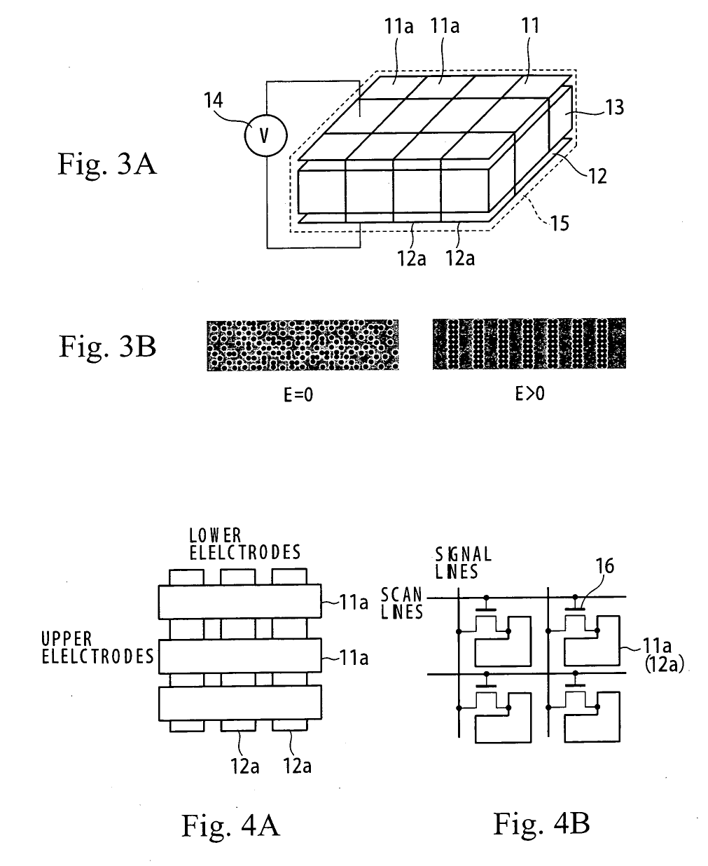

In the electrorheological fluid device, the viscosity of the electrorheological fluid can be partially changed by selectively driving the pair of electrodes, each of which is divided into a plurality of electrodes. FIGS. 3A and 3B show an example in which the electrodes 11, 12 are divided into electrode patterns 11a, 12a in a matrix form. In this case, the electrode patterns 11a, 12a can individually change the viscosity of the electrorheological fluid, and a structure of the device is such that a plurality of electrorheological fluid elements each having an electrorheological fluid disposed between the electrode patterns 11a, 12a are arranged on the same plane.

The electrode patterns 11a, 12a in a matrix form constituting the individual electrorheological fluid elements can be driven in a passive matrix mode or an active matrix mode. The passive matrix mode or active matrix mode is one of the driving modes for liquid-crystal display and, for example, the passive matrix mode is a mode in which, as shown in FIG. 4A, conductor wires (strip-form electrode patterns 11a and 12a) are arranged in two directions, i.e., in the X-axis direction and the Y-axis direction, and a voltage is applied in both the X- and Y-axis directions to drive liquid crystal (electrorheological fluid in this case) at the intersections. The electrorheological fluid is arranged at each intersection so that the electrorheological fluid is disposed between the conductor wire in the X-axis direction and the conductor wire in the Y-axis direction. The passive matrix mode has a feature such that the structure is simple and hence the cost is low and the yield is high. In the active matrix mode, as shown in FIG. 4B, an active element 16, for example, a thin film transistor and an individual electrode (corresponding to the electrode pattern 11a or electrode pattern 12a) are arranged per electrorheological fluid element. The active element 16 is switched on or off by the voltage of a signal line and a scan line, and, when the active element 16 is in the on state, a voltage is applied to a desired electrorheological fluid through the individual electrode and changes the viscosity of the electrorheological fluid. Therefore, only a desired electrorheological fluid element can be surely operated.

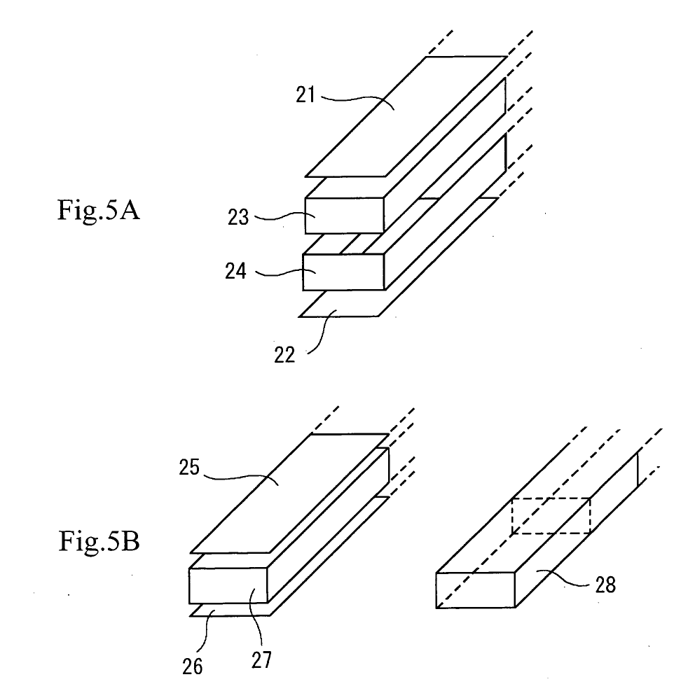

FIGS. 5A and 5B are views showing examples of the construction of the electrorheological fluid device. FIG. 5A is an exploded view showing an example in which an electrorheological fluid 23 mentioned above is disposed between a pair of strip-form electrodes 21, 22 and a container 24 for covering the side portion of the electrorheological fluid 23 is formed between the electrodes 21, 22. The electrorheological fluid 23 here is a fluid and hence has an indefinite shape, and the shape of the electrorheological fluid 23 is shown according to the shape of the container 24 covering the side portion of the electrorheological fluid. The container 24 is comprised of an insulating material having flexibility, and can be constituted by, for example, an insulating thin rubber sheet or synthetic resin sheet, and the material for constituting the container is not limited to a single material, and a composite film comprised of a plurality of material layers laminated together or the like may be used. The electrodes 21, 22 are electrode members for applying a voltage to the electrorheological fluid 23, and a desired voltage is applied by a not shown power source or the like to change the viscosity of the electrorheological fluid 23. The container 24 is liquid-tightly connected to a pair of strip-form electrodes 21, 22 at their edge portions, and therefore the electrorheological fluid 23 in the container is surely held between the strip-form electrodes 21, 22.

FIG. 5B is views showing another example of the construction of the electrorheological fluid device. An electrorheological fluid 27 mentioned above is disposed between a pair of strip-form electrodes 25, 26, and a bag container 28 for completely covering both the electrodes 25, 26 and the electrorheological fluid 27 is formed. When the bag container 28 is formed, the container 28 is also present on the opposite side of the facing surfaces of the electrodes 25, 26, and the electrorheological fluid 27 is held inside of the container 28. The bag container 28 is comprised of an insulating material having flexibility, and can be constituted by, for example, an insulating thin rubber sheet or synthetic resin sheet, and the material for constituting the bag container is not limited to a single material, and a composite film comprised of a plurality of material layers laminated together or the like may be used. The electrodes 25, 26 and the container 28 are not necessarily in contact with each other.

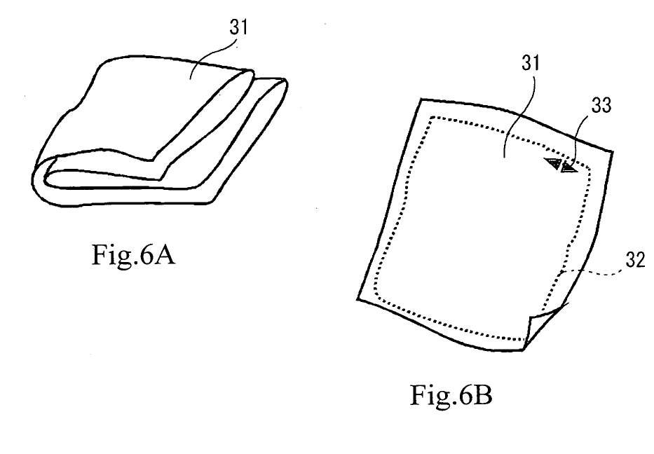

In the strip-form electrorheological fluid device, by controlling the elastic coefficient of the electrorheological fluid, the shape of the electrorheological fluid device can be controlled. Specifically, FIGS. 6A and 6B show an electronic apparatus 31 having such portability that the apparatus can be folded or rounded, wherein FIG. 6A is a perspective view showing the electronic apparatus 31 which has been folded, and FIG. 6B is a perspective view showing the electronic apparatus 31 which has been unfolded.

The electronic apparatus 31 is comprised of a thin, lightweight material having flexibility totally, for example, a flexible display device or a so-called electronic paper, and an electrorheological fluid device 32 is arranged in a pattern such that the electronic apparatus 31 is rimmed with the electrorheological fluid device 32. A switch 33 is formed on the surface of the electronic apparatus 31, and two triangular buttons of the switch 33 control the electrorheological fluid device 32 as a rim for the electronic apparatus 31 to be turned on or off.

The display device in the electronic apparatus 31 includes a display section and a driving section, which are not shown, and, as the display section, a display device comprised of microcapsules having flexibility utilizing an electrophoresis effect, an electrochromic display device or electrode position display device which achieve light emission in accordance with an electrochemical action, or the like can be used. The display section is arranged in, for example, the center portion of the substantially sheet-form electronic apparatus 31 so that the electronic apparatus totally has a flexible construction. The driving section is a circuit portion for controlling the coloring of pixels in the display section, and is preferably flexible and therefore an organic element, such as a thin film organic transistor, can be used as the driving circuit. The organic transistor has a construction such that it is comprised of a thin film formed from an organic semiconductor (e.g., polymer material having conductive properties) or the like and carriers passing through the channel in the semiconductor are controlled. The electronic apparatus 31 is produced in this way using a flexible display section and a flexible driving section, and hence this apparatus has such favorable portability that it can be folded or rounded.

When the electronic apparatus is changed from the folded state shown in FIG. 6A to the unfolded state shown in FIG. 6B, the electrorheological fluid device 32 as a rim for the electronic apparatus 31 is changed from the off state to the on state. Then, an electric field is formed between a not shown pair of electrodes in the electrorheological fluid device 32, and the electrorheological fluid contained in the electrorheological fluid device 32 is changed to be solid which aligns with the electric field. As a result, the electrorheological fluid device 32 arranged to be a rim for the electronic apparatus 31 functions as a frame for supporting the sheet, so that a user can easily hold the electronic apparatus 31 in the unfolded state.

When after the user has finished watching the screen of the display section and places again the electronic apparatus in a pocket or bag to carry it, the switch of the electronic apparatus 31 held in the unfolded state is operated to change the electrorheological fluid device 32 as a rim for the electronic apparatus 31 from the on state to the off state. Accordingly, the electric field between the electrodes in the electrorheological fluid device 32 is cleared, and the electrorheological fluid, which is in a solid state in the electrorheological fluid device 32 during the on state, is changed to be a fluid as usual, so that the electrorheological fluid device 32 does not have such hardness that it functions as a frame for the electronic apparatus 31, thus making it easy to change the shape of the apparatus, e.g., to fold the apparatus.

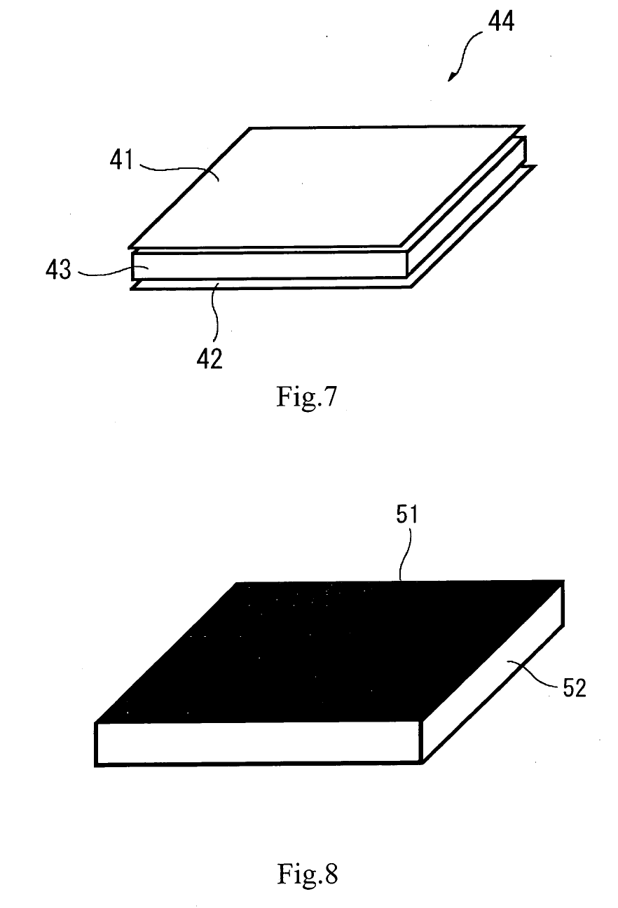

Next, patterns of arrangement of the electrorheological fluid device will be described with reference to FIGS. 7 to 20. First, FIG. 7 is an exploded perspective view showing the structure of a substantially flat-plate form electrorheological fluid device 44, in which an electrorheological fluid 43 is disposed between a pair of substantially flat-plate form electrodes 41, 42. The structure shown in FIG. 7 is similar to the above-described structure shown in FIG. 2A. The substantially flat-plate form electrorheological fluid device 44 changes the plane pattern of the electrodes 41, 42 and has a container having a shape selected according to the changed plane pattern of the electrodes 41, 42. It is preferred that the electrodes 41, 42 are formed from a conductive material having flexibility, and an electric field for control is generated between the electrodes 41, 42 by a not shown power source. A spacer comprised of an insulator or the like for preventing the occurrence of short-circuiting can be formed between the substantially flat-plate form electrodes 41, 42. Hereinbelow, various plain patterns of the electrorheological fluid device are described with reference to FIGS. 8 to 16.

FIG. 8 shows an example in which an electrorheological fluid device is formed into a substantially flat shape. Specifically, a substantially flat-plate form electrorheological fluid device 51 is formed on the entire top surface of a substantially flat-plate form substrate 52. As the structure of the electrorheological fluid device 51, specifically, the structure shown in FIG. 7 is applied, namely, a structure in which an electrorheological fluid is disposed between a pair of substantially flat-plate form electrodes and the whole of the electrorheological fluid and the electrodes are completely covered with a container. In the example of FIG. 8, the electrorheological fluid device has a pattern in plane in which it covers all over the top surface of the substrate, and therefore the texture or hardness of the entire surface of the electrorheological fluid device 51 can be controlled according to the on-off control for the electrorheological fluid device 51, and, for example, when the substrate 52 is comprised of a flexible material, the substrate 52, which is being bent, can be controlled to spread. The substrate 52 can be incorporated as apart of the electronic apparatus as mentioned above, for example, a part of a flat-type display device, or a part of a wearable device directly fitted to a human body. This applies to the substrates below.

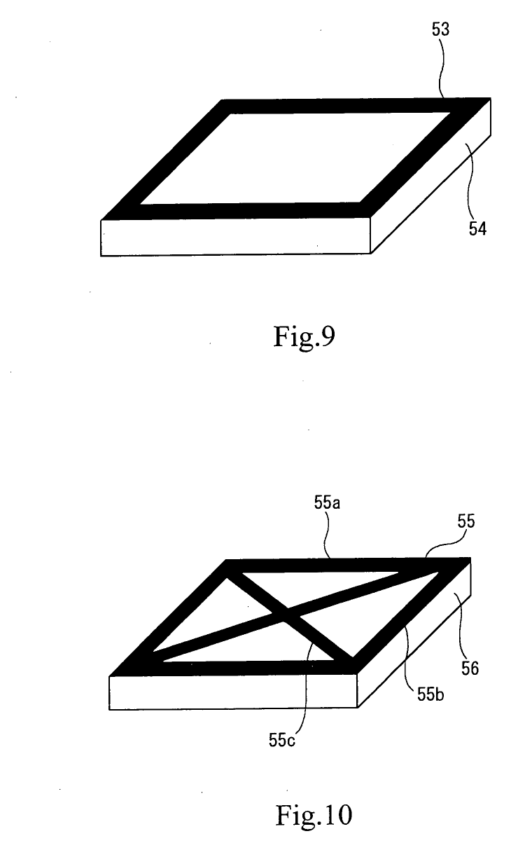

FIG. 9 shows an example in which an electrorheological fluid device is formed into a substantially square shape. An electrorheological fluid device 53 in a strip form is formed on a substantially flat-plate form substrate 54 to form a pattern such that the device is present along the whole edge portion of the substrate on the side of the top surface. The electrorheological fluid device 53 has, specifically, the structure shown in FIG. 7 in which an electrorheological fluid is disposed between a pair of substantially strip-form electrodes and the whole of the electrorheological fluid and the electrodes are completely covered with a container. In the example of FIG. 9, the substantially strip-form electrorheological fluid device 53 extends along the edge portion of the substrate 54, and therefore, when controlled to be in the on state, the substantially strip-form electrorheological fluid device 53 becomes hard and functions as a frame for the substrate 54, so that a user can easily hold the substrate 54. The substantially strip-form electrorheological fluid device 53 extends in the crossing two directions, and is formed along the edge portion both in the horizontal direction (lateral direction) and in the vertical direction (longitudinal direction) as viewed from the front side of the substrate 54 which stands upwards.

FIG. 10 shows an example of the combination of the pattern of FIG. 9 and a pattern extending along the diagonals. An electrorheological fluid device 55 of FIG. 10 includes a horizontal portion 55a, formed on the end portion of a substrate 56, extending in the horizontal direction (lateral direction) as viewed from the front side of the substrate 56 which stands upwards, a vertical portion 55b, formed on the end portion of the substrate 56, extending in the vertical direction (longitudinal direction) as viewed from the front side of the substrate 56 which stands upwards, and a diagonal portion 55c extending along the diagonals. The electrorheological fluid device 55 has, specifically, the structure shown in FIG. 7 in which an electrorheological fluid is disposed between a pair of substantially strip-form electrodes and the whole of the electrorheological fluid and the electrodes are completely covered with a container. The substantially strip-form electrorheological fluid device 55 extends in the crossing two directions, i.e., in the horizontal direction (lateral direction) and in the vertical direction (longitudinal direction), and further the diagonal portions 55c extending along the diagonals are added to the structure, and, especially when the substrate 56 has a large area, the diagonal portions 55c extending along the diagonals improve the holding properties for the substrate 56.

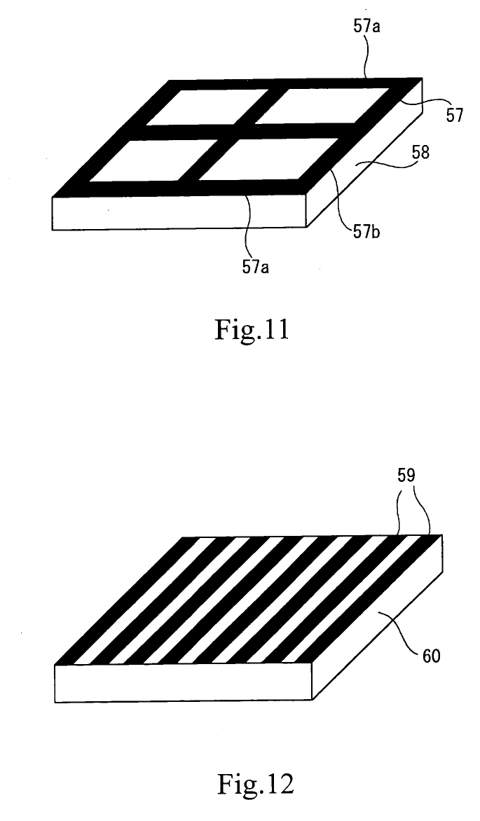

FIG. 11 shows an example in which an electrorheological fluid device is formed into a substantially square-shaped pattern having crisscross-shaped portion therein. An electrorheological fluid device 57 of FIG. 11 includes horizontal portions 57a, formed on the both end portions and the middle portion of a substrate 58, extending in the horizontal direction (lateral direction) as viewed from the front side of the substrate 58 which stands upwards, and vertical portions 57b, formed on the both end portions and the middle portion of the substrate 58, extending in the vertical direction (longitudinal direction) as viewed from the front side of the substrate 58 which stands upwards. The electrorheological fluid device 57 has, specifically, the structure shown in FIG. 7 in which an electrorheological fluid disposed between a pair of substantially strip-form electrodes and the whole of the electrorheological fluid and the electrodes are completely covered with a container. The substantially strip-form electrorheological fluid device 57 extends in the crossing two directions, i.e., in the horizontal direction (lateral direction) and in the vertical direction (longitudinal direction), and, even when the substrate 58 especially has a large area, the horizontal portion 57a and vertical portion 57b passing through the middle portion improve the holding properties for the substrate 58.

FIG. 12 shows an example of pattern in which a plurality of strip-shaped electrorheological fluid devices are arranged so that they are parallel to one another. In FIG. 12, a plurality of strip-shaped electrorheological fluid devices 59 extend on the top surface of a substrate 60 at predetermined intervals in the vertical direction (longitudinal direction) as viewed from the front side of the substrate 60 which stands upwards. Each electrorheological fluid device 59 has, specifically, the structure shown in FIG. 7 in which an electrorheological fluid is disposed between a pair of substantially strip-form electrodes and the whole of the electrorheological fluid and the electrodes are completely covered with a container. For example, when the substrate 60, which is comprised of a flexible structure, is bent in the vertical direction, the strip-shaped electrorheological fluid devices 59 formed the top surface of the substrate 60 are once bent together, but, by controlling the strip-form electrorheological fluid devices 59 to be in the on state, the electrorheological fluid devices 59 change in shape so that they spread into a line form, namely, the devices bent in the vertical direction are controlled so that they totally spread.

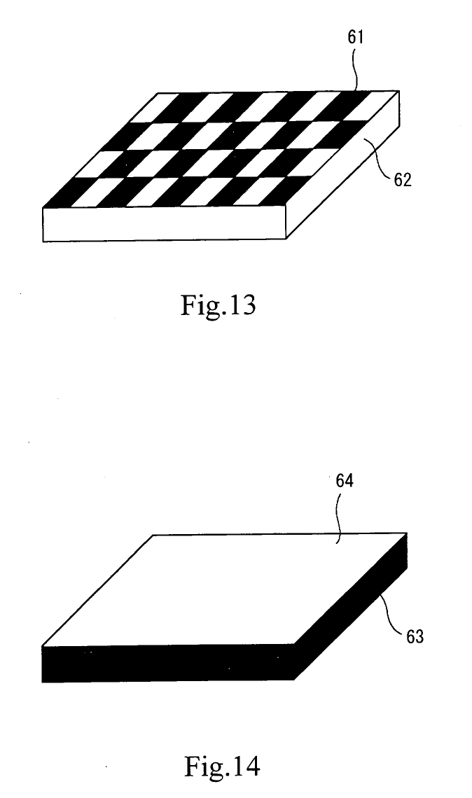

FIG. 13 shows an example in which substantially rectangular electrorheological fluid devices are arranged in a checkered pattern. In FIG. 13, a plurality of substantially rectangular electrorheological fluid devices 61 are arranged in a checkered pattern on the top surface of a substrate 62. Each electrorheological fluid device 61 here has, specifically, the structure shown in FIG. 7 in which an electrorheological fluid is disposed between a pair of substantially strip-form electrodes and the whole of the electrorheological fluid and the electrodes are completely covered with a container. The electrorheological fluid devices 61 arranged in a checkered pattern are formed and hence about half of the substrate 62 is covered with the electrorheological fluid devices 61, and, even when the substrate 62 has a large area, the electrorheological fluid devices 61 improve the holding properties for the substrate 62. In addition, about half of the substrate 62 is covered with the electrorheological fluid devices 61 and hence, a mixture of the texture of the surface of the substrate 62 and the changeable texture of the surface of each electrorheological fluid device 61 can be controlled.

FIG. 14 shows an example in which an electrorheological fluid device 63 is formed on the sidewall of a substrate 64. The strip-shaped electrorheological fluid device 63 is formed on the sidewall of the substantially flat-plate form substrate 64 so as to around the sidewall. The electrorheological fluid device 63 formed on the sidewall of the substrate 64 has, specifically, the structure shown in FIG. 7 in which an electrorheological fluid is disposed between a pair of substantially strip-form electrodes and the whole of the electrorheological fluid and the electrodes are completely covered with a container. When the electrorheological fluid device 63 having this pattern is formed, like in the example shown in FIG. 9 in which a substantially square-shaped electrorheological fluid device is formed, when the electrorheological fluid device 63 is controlled to be in the on state, the electrorheological fluid device 63 functions as a frame for the substrate 64.

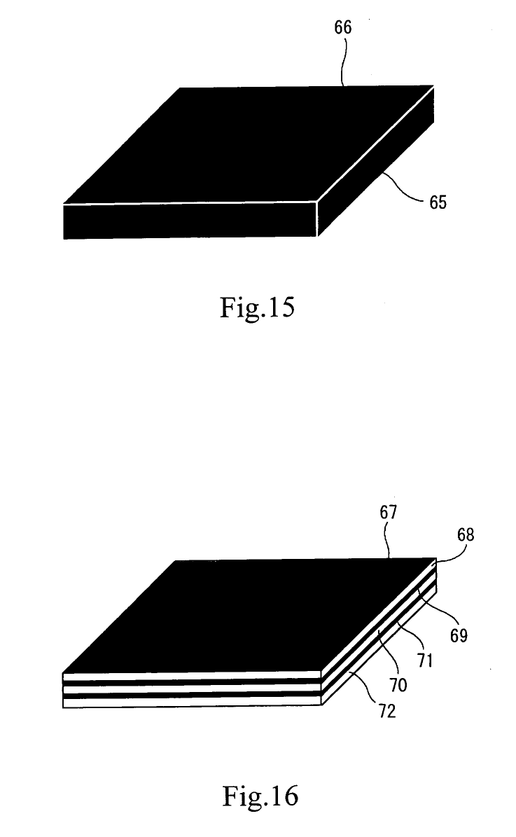

FIG. 15 shows an example in which electrorheological fluid devices 65, 66 are formed on the entire surface of a not shown substrate. The electrorheological fluid device 65 is formed on the sidewall of the substantially flat-plate form substrate, and the electrorheological fluid device 66 is formed the top surface of the substantially flat-plate form substrate. Although it is know shown, the electrorheological fluid device may be formed on the bottom surface of the substrate. When the electrorheological fluid devices 65, 66 are formed on the entire surface of the substrate as mentioned above, a user can touch the hardness or texture produced by the electrorheological fluid devices 65, 66 at any portion of the devices, and the change of the feeling texture can be controlled by the voltage applied to the electrodes in the electrorheological fluid devices 65, 66.

FIG. 16 shows an example of a structure in which three laminates, each including a substantially flat-plate form electrorheological fluid device stacked on a substantially flat-plate form substrate, are stacked on one another. Specifically, a substantially flat-plate form electrorheological fluid device 71 is formed on a substantially flat-plate form substrate 72, and a substantially flat-plate form substrate 70 is stacked on the electrorheological fluid device 71. A substantially flat-plate form electrorheological fluid device 69 is formed on the substantially flat-plate form substrate 70, and a substantially flat-plate form substrate 68 is stacked on the electrorheological fluid device 69. Further, a substantially flat-plate form electrorheological fluid device 67 is formed on the substantially flat-plate form substrate 68. In the stacked structure, the apparatus which is being folded can be controlled to spread and vice versa, and this structure is effective especially when the effect of controlling the shape is weak in the structure comprised of one layer.

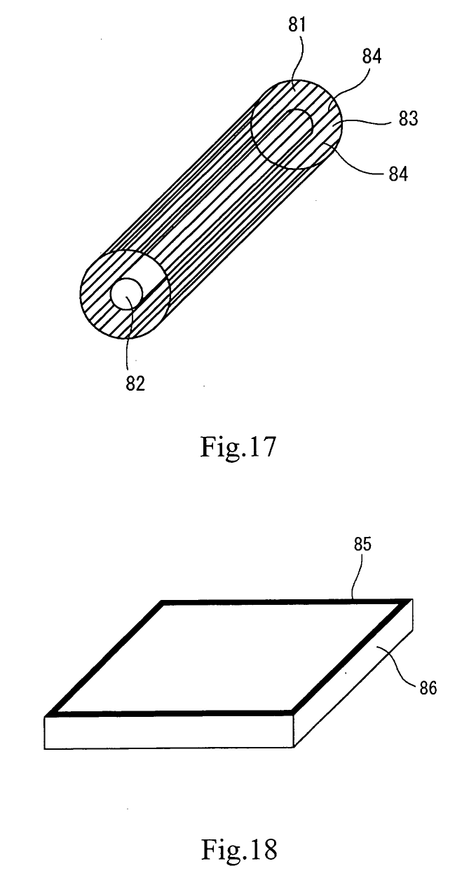

Next, an electrorheological fluid device of another structure is described with reference to FIG. 17. This electrorheological fluid device includes an outer electrode 81 having a cylindrical form and an inner electrode 82 having a round bar form, and an electrorheological fluid is filled between the outer electrode 81 and the inner electrode 82. The outer electrode 81 has, for example, a totally flexible construction, namely, a structure in which a plurality of wires 84 capable of being easily bent are disposed inside a tube 83 made of a flexible synthetic resin material, and, when the electrorheological fluid device is bent, the outer electrode can flexibly change in its shape. In the example shown in the figure, the wires 84 are disposed in the tube 83 made of a flexible synthetic resin material, but a thin film of a conductive material, such as a metal, may be formed inside the tube 83, or a conductive coating composition may be applied to the inner wall of the tube 83 to form an electrode. Like the outer electrode 81, the inner electrode 82 having a round bar form can be formed using a flexible material, and can be changed in its shape or bent. A spacer comprised of an insulator or the like for preventing the occurrence of short-circuiting can be formed between the electrodes 81, 82.

The electrorheological fluid to be filled is a fluid such that, as mentioned above, application of an electric field to electrodes causes the substance disposed between the electrodes to remarkably change in viscosity, more specifically, a fluid which contains fine particles having polarizable properties and having a diameter of about 0.1 to 100 μm dispersed in electrical insulating liquid (dispersion medium), when an electric field is applied to the suspended fluid from the electrodes 81, 82, the elastic coefficient of the fluid remarkably changes. Examples of materials used in the electrorheological fluid include amorphous silicate ceramic, and, especially, it is known that aluminosilicate shows a strong electrorheological effect. Not only aluminosilicate but also a conductive organic material or polymer material can constitute the fine particles to be dispersed. The polymer material generally has electronic conduction properties due to the π-conjugated bond structure. In addition, carbonaceous materials and fullerene are also useful as a dispersible material, and further, it is known that superconducting materials have an electrorheological effect in, for example, silicone oil at room temperature, and the superconducting materials may be used. Various patterns of the electrorheological fluid device are described below with reference to FIGS. 18 to 20.

FIG. 18 shows an example in which an electrorheological fluid device is formed into a substantially square-shape. An electrorheological fluid device 85 is formed on a substantially flat-plate form substrate 86 to form a pattern such that the device is present along the whole edge portion of the substrate on the side of the top surface. The electrorheological fluid device 85 has, specifically, the structure shown in FIG. 17 in which an electrorheological fluid is disposed between a cylindrical outer electrode and a cylindrical inner electrode and the whole of the electrorheological fluid and the electrodes are completely covered with a container in a tube form. In the example of FIG. 18, the thin cylindrical electrorheological fluid device 85 extends along the edge portion of the substrate 86, and therefore, when controlled to be in the on state, the thin cylindrical electrorheological fluid device 85 becomes hard and functions as a frame for the substrate 86, so that a user can easily hold the substrate 86 when it is held. The substantially strip-form electrorheological fluid device 85 extends in the crossing two directions, and is formed along the edge portion both in the horizontal direction (lateral direction) and in the vertical direction (longitudinal direction) as viewed from the front side of the substrate 86 which stands upwards. The substrate 86 can be incorporated as a part of the electronic apparatus as mentioned above, for example, a part of a flat-type display device, or a part of a wearable device directly fitted to a human body. This applies to the substrates below.

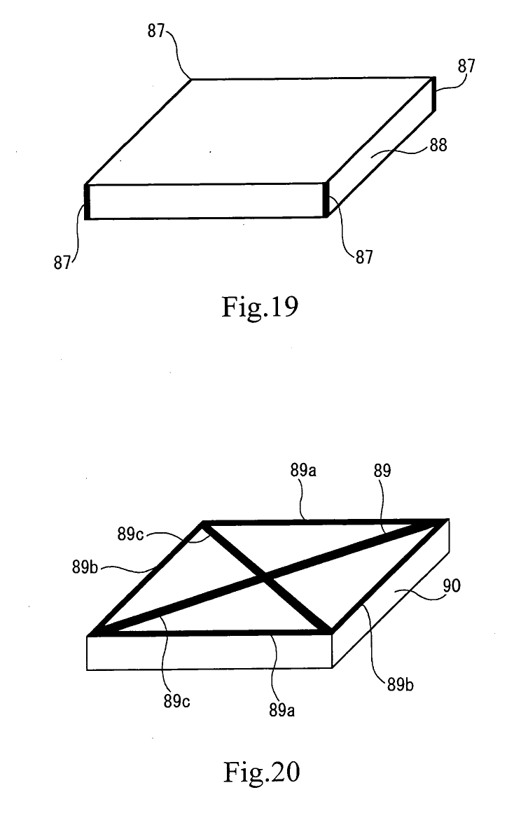

FIG. 19 shows an example in which electrorheological fluid devices are fitted to the four corner portions of a substantially flat-plate form substrate. In FIG. 19, electrorheological fluid devices 87 are respectively formed at the four corner portions of a substantially flat-plate form substrate 88 so that the electrorheological fluid devices extend in the direction perpendicular to the main surface of the substrate to connect the bottom side to the top side. The electrorheological fluid device 87 has, specifically, the structure shown in FIG. 17 in which an electrorheological fluid is disposed between a cylindrical outer electrode and a cylindrical inner electrode and the whole of the electrorheological fluid and the electrodes are completely covered with a container in a tube form. In the structure in which the electrorheological fluid devices 87 are respectively formed at the four corner portions of the substantially flat-plate form substrate 88, the application of a voltage to the electrorheological fluid devices 87 can control the corner portions to be hard, and this structure is effective when the corners are required to be hard.

FIG. 20 shows an example of the combination of the pattern of FIG. 18 and a pattern extending along the diagonals. An electrorheological fluid device 89 of FIG. 20 includes a horizontal portion 89a, formed on the end portion of a substrate 90, extending in the horizontal direction (lateral direction) as viewed from the front side of the substrate 90 which stands upwards, a vertical portion 89b, formed on the end portion of the substrate 90, extending in the vertical direction (longitudinal direction) as viewed from the front side of the substrate 90 which stands upwards, and a diagonal portion 89c extending along the diagonals. The electrorheological fluid device 89 has, specifically, the structure shown in FIG. 17 in which an electrorheological fluid is disposed between a cylindrical outer electrode and a cylindrical inner electrode and the whole of the electrorheological fluid and the electrodes are completely covered with a container in a tube form. The electrorheological fluid device 89 extends in the crossing two directions, i.e., in the horizontal direction (lateral direction) and in the vertical direction (longitudinal direction), and further the diagonal portions 89c extending along the diagonals are added to the structure, and, especially when the substrate 90 has a large area, the diagonal portions 89c extending along the diagonals improve the holding properties for the substrate 90.

Next, another embodiment is described with reference to FIGS. 21A to 21D. FIG. 21A shows an example in which first electrorheological fluid devices 101 and electrorheological fluid devices 102, 103 are formed in a housing 100 for the electronic apparatus so that the first electrorheological fluid devices 101 are arranged between the predetermined two sides of the housing in parallel with one another at substantially equally intervals and the electrorheological fluid devices 102, 103 are arranged along, respectively, the remaining two sides of the housing perpendicular to the first electrorheological fluid devices 101. In the housing 100 which is totally flexible, when both the electrorheological fluid devices 101 and the electrorheological fluid devices 102, 103 are tuned on (a voltage is applied thereto), the rigidity in the directions at right angles is secured, so that the housing 100 in a substantially flat-plate form is totally maintained. In contrast, when the electrorheological fluid devices 101 are turned on and the electrorheological fluid devices 102, 103 are turned off, the rigidity in the extending direction of the electrorheological fluid devices 101 is kept, but the rigidity in the extending direction of the electrorheological fluid devices 102, 103 clears, so that the housing becomes flexible in this direction. As a result, as shown in FIG. 21B, bent portions 104 parallel to the first electrorheological fluid devices 101 are formed in the housing 100, and thus the housing 100 is totally in a curved shape. When a voltage is applied to a pair of electrodes in each of the electrorheological fluid devices 102, 103 to turn them on again, the electrorheological fluids contained in the devices are changed to be in a solid state to cause the electrorheological fluid devices 102, 103 to spread, enabling the housing 100 to return to a non-curved, substantially flat-plate form state shown in FIG. 21A from the curved state shown in FIG. 21B.

Similarly, FIG. 21C shows one example of a housing 105 for the electronic apparatus, which is capable of being bent at, for example, a right angle. The previous example is an example in which the housing is deformed (bent) along the long side of the housing at any portions, but this example is an example in which the housing is deformed along the long side of the housing only at a portion. The housing can be partially deformed in this way, and, in this example, the housing 105 can be bent at a right angle. In this example, as shown in FIG. 21C, two electrorheological fluid devices 106 are arranged at an almost middle portion of the housing 105, and electrorheological fluid devices 107, 108 are arranged along, respectively, the two sides of the housing perpendicular to the electrorheological fluid devices 106. When both the electrorheological fluid devices 106 and the electrorheological fluid devices 107, 108 are turned on (a voltage is applied thereto), like in the previous example, the rigidity in the directions at right angles is secured, so that the housing 105 in a substantially flat-plate form is totally maintained. On the other hand, when the electrorheological fluid devices 106 are turned on and the electrorheological fluid devices 107, 108 are turned off, the rigidity in the extending direction of the electrorheological fluid devices 106 is kept, and the rigidity in the extending direction of the electrorheological fluid devices 107, 108 cleared. As a result, as shown in FIG. 21D, bent portions 109 are formed between the electrorheological fluid devices 106, so that the housing is bent at a right angle. When the electrorheological fluid devices 107, 108 are turned on again, the electrorheological fluids contained in the devices are changed to be in a solid state to cause the electrorheological fluid devices 107, 108 to spread, enabling the housing 105 to return to a non-curved substantially flat-plate form state shown in FIG. 21C from the curved state shown in FIG. 21D.

By disposing the electrorheological fluid devices 101, 102, 103, 106, 107, 108 at the curved portions or bent portions in the housings 100, 105 for the electronic apparatus and changing the voltage applied to these devices as mentioned above, the shape of the housings 100, 105 can be controlled. In this case, a mechanical operating component, such as a special hinge or actuator, is not required, and the present embodiment has an advantage in that the apparatus is generally small in size and lightweight.

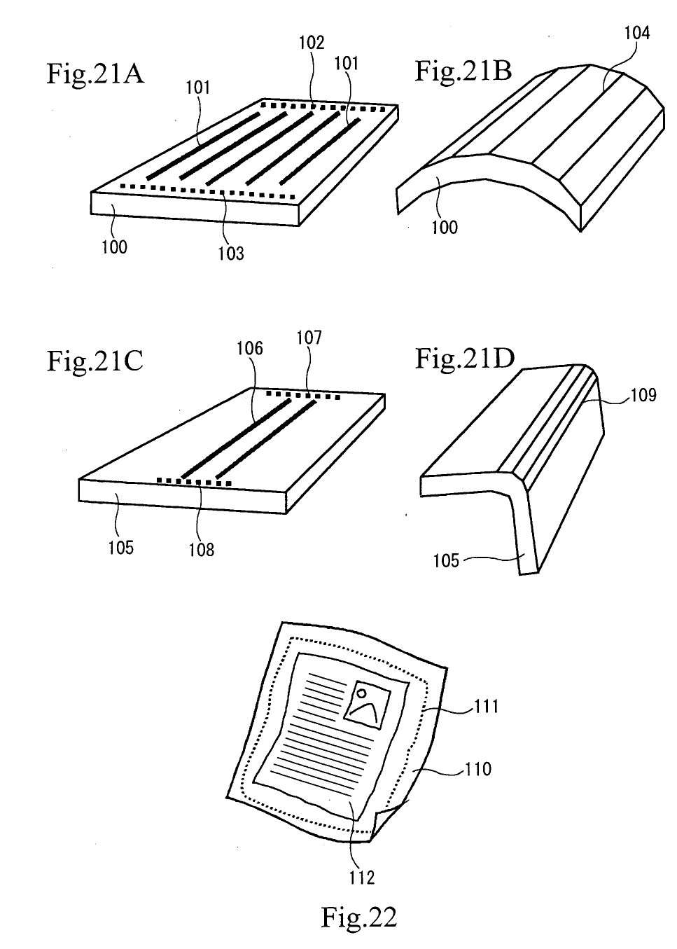

FIG. 22 shows an example of a flexible display apparatus as another embodiment. A flexible display apparatus 110 has a flexible sheet-form apparatus body, and a display section 112 formed at the middle portion of the apparatus body. In addition, although it is not shown, a driving section or radio communication circuit portion is formed around the display section, and further a sheet-form loudspeaker section, touch panel section, or the like is formed. An electrorheological fluid device 111 is formed along the edge portion of the flexible display apparatus 110. The electrorheological fluid device 111 has a structure in which an electrorheological fluid is disposed between a pair of electrodes and the whole of the electrorheological fluid and the electrodes are completely covered with a container, and, when a voltage is applied to the electrodes, the electrorheological fluid contained in the device is changed to be in a solid state to cause the electrorheological fluid device 111 to spread, thus controlling the flexible display apparatus 110 to spread. Conversely, when controlling the device so that no voltage is applied to the electrodes, the electrorheological fluid contained in the device is changed to be in a liquid state, so that the flexible display apparatus 110 can be even easily folded.

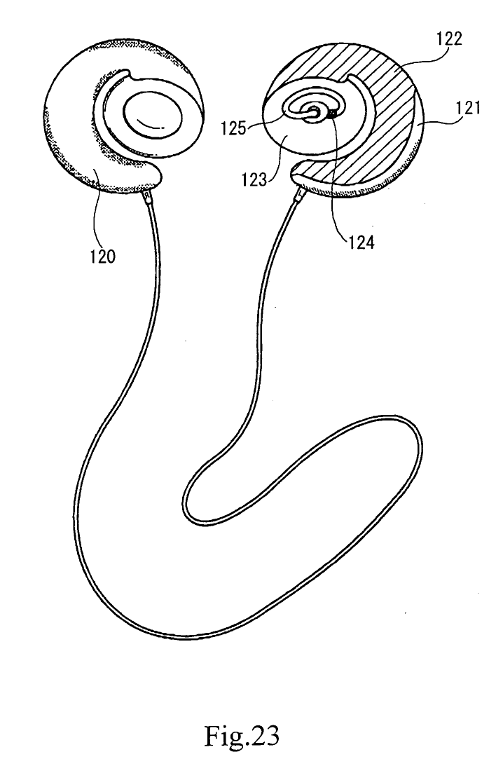

FIG. 23 shows an example of earphone-type network audio equipment. A power source, an audio reproducing circuit section, a communication circuit section, and the like are incorporated into a pair of contacting sections 120, 121 which contact the back of ears of a user, and especially on the outside of the contacting sections 120, 121, an electrorheological fluid device 122 is formed at a portion which contacts the ears. The electrorheological fluid device 122 is controlled to be soft when a user uses the equipment while pressing the contacting sections 120, 121 against the back of the ears, and the electrorheological fluid device softened lowers the load of the user enjoying music for a long time. A leading path 125 for leading, for example, bass sound from the back side to the ear side is formed in part of a loudspeaker section 123, and an electrorheological fluid device 124 is formed at the end portion of the leading path 125. The electrorheological fluid device 124 opens the leading path 125 when a voltage is applied or closes the leading path 126 when the application of voltage is stopped, thus switching the loudspeaker for middle-high sound. The electrorheological fluid device 124 is small and lightweight, and hence realizes the above control without sacrificing the portability of the earphone-type network audio equipment.

The electrorheological fluid device can be applied to, for example, part of a controller of a home-use game machine as another example of the electronic apparatus of the present invention. A user touches a control section of the controller by fingers, and the feeling of touch is controlled by the electrorheological fluid device. For example, if a game player is defeated in a fighting game, the electrorheological fluid device is controlled to become soft in order to improve the realistic sensations in the game.

An explanation is made on the examples of the electrorheological fluid device in which a pair of strip- form, sheet-form, or cylindrical electrodes are used, but both or one of the electrodes may be formed from a leaf spring or a coiled spring, and, in this case, the elasticity of the spring itself contributes to the change of the shape.

By using the electrorheological fluid device or electronic apparatus of the present invention, the hardness, tension, texture, shape, or the like of the apparatus can be electrically controlled. The electrorheological fluid to be electrically controlled is easy to reduce in size or weight, and has a high response rate, and further can be reversibly controlled by canceling the application of voltage. Therefore, the hardness, tension, texture, shape, or the like of the electronic apparatus can be added as a new function to the electronic apparatus which is conventionally merely a hard apparatus, thus considerably broadening the range of the application.

1. An electrorheological fluid device, characterized by comprising:
a container capable of containing fluid internally;
a pair of electrodes having flexibility, disposed in said container so as to oppose each other; and
an electrorheological fluid contained in said container and disposed between said electrodes, and having an elastic property changeable in accordance with an electric field generated between said electrodes.

2. The electrorheological fluid device according to claim 1, characterized in that said container is constituted by flexible materials.

3. The electrorheological fluid device according to claim 1, characterized in that said pair of electrodes comprises dot-form, sheet-form, or strip-form opposed electrodes.

4. The electrorheological fluid device according to claim 1, characterized in that said pair of electrodes comprises one shaft-form electrode and another electrode disposed on peripheral border so as to oppose each other.

5. The electrorheological fluid device according to claim 1, characterized in that said pair of electrodes extend in the direction of extending said container.

6. The electrorheological fluid device according to claim 1, characterized in that at least two pairs of said pair of electrodes are formed, wherein an electric field generated by one pair of electrodes and an electric field generated by the other pair of electrodes are crossed.

7. An electrorheological fluid device, characterized by comprising:
a plurality of electrorheological fluid elements;
said electrorheological fluid element having:
a container capable of containing fluid internally;
a pair of electrodes having flexibility, disposed in said container so as to oppose each other; and
an electrorheological fluid having an elastic property changeable in accordance with an electric field generated between said electrodes, said electrorheological fluid being contained in said container and disposed between said electrodes.

8. The electrorheological fluid device according to claim 7, characterized in that said electrorheological fluid devices are arranged to be a substantially flat-plate form.

9. The electrorheological fluid device according to claim 7, characterized in that said plurality of arranged electrorheological fluid devices are driven by a passive matrix mode or an active matrix mode.

10. An electronic apparatus, characterized by comprising:
an apparatus body having flexibility;
a container capable of containing fluid internally, attached to said apparatus body;
a pair of electrodes having flexibility, disposed in said container so as to oppose each other; and
an electrorheological fluid contained in said container and disposed between said electrodes, and having an elastic property changeable in accordance with an electric field generated between said electrodes.

11. The electronic apparatus according to claim 10, characterized in that said container is constituted by flexible materials.

12. The electronic apparatus according to claim 10, characterized in that said container is formed in a portion contacting a human body.

13. The electronic apparatus according to claim 10, characterized in that said apparatus body is provided with an image display section.

14. The electronic apparatus according to claim 10, characterized in that an organic transistor is provided as a control device.

15. The electronic apparatus according to claim 10, characterized in that said image display section is provided with an organic transistor as a control device.

16. An electronic apparatus, characterized by comprising:
an apparatus body;
a container having flexibility and capable of containing fluid internally, attached to said apparatus body;
at least a pair of electrodes having flexibility, disposed in said container so as to oppose each other; and
an electrorheological fluid contained in said container and disposed between said electrodes, and having an elastic property changeable in accordance with an electric field generated between said electrodes.

17. The electronic apparatus according to claim 16, characterized in that said container is provided on a path formed in a part of said apparatus body, and performs an open/close operation of said path in accordance with a property change of said electronic electrorheological fluid contained in said container.

18. The electronic apparatus according to claim 16, characterized in that said container is formed at an open/close section of said apparatus body, and performs an open/close operation of said open/close section in accordance with a property change of said electronic electrorheological fluid contained in said container.

19. An electronic apparatus, characterized by comprising:
a sheet-form body having flexibility;
a container capable of containing fluid internally, attached to said sheet-form body;
at least a pair of electrodes having flexibility, disposed in said container so as to oppose each other; and
an electrorheological fluid contained in said container and disposed between said electrodes, and having an elastic property changeable in accordance with an electric field generated between said electrodes.

20. The electronic apparatus according to claim 19, characterized in that said container extends in one direction on said sheet-form body or in said sheet-form body.

21. The electronic apparatus according to claim 19, characterized in that said sheet-form body is able to be kept in a rolled-shape.

22. The electronic apparatus according to claim 19, characterized in that said sheet-form body is able to be kept in a folded-shape.

23. The electronic apparatus according to claim 19, characterized in that said container is constituted by flexible materials.
